(19) United States
(12) Patent Application Publication
(10) Pub. No.: US 2010/0007432 A1
(43) Pub. Date: Jan. 14, 2010

(54) Orthomode junction assembly with associated filters for use in an antenna feed system

(76) Inventor: Jaroslaw Uher, Pointe-Claire (CA)

Correspondence Address: Franz BONSANG;c/o EQUINOX PROTECTION, 410-1500, Du College, St-Laurent, QC, H4L 5G6, CA

(21) Appl. No.: 12/458,490

(22) Filed: Jul. 14, 2009

Related U.S. Application Data
(60) Provisional application No. 61/129,711, filed on Jul. 14, 2008.

(51) Int. Cl. H03H 7/46

(52) U.S. Cl. 333/132

(57) ABSTRACT

A reverse orthomode junction assembly with associated filters for use in an antenna feed system for transmitting a first electromagnetic signal at a first frequency range lower than the second frequency range of a receive second electromagnetic signal. The assembly includes an orthomode junction with an antenna port for connecting to an antenna, an opposed generally coaxial first signal port to transmit the first signal, and a generally perpendicular second signal port, located there between, to receive the second signal. A first signal channel having on-axis second signal reject filters connects to the first port; and a second signal channel having cross-axis first signal reject filters connects to the second port. The use of a magic-tee as a combiner for the receive signal provides tracking capability to the antenna feed system.

### CROSS REFERENCE TO RELATED APPLICATIONS

Benefit of priority of US Provisional Application for Patent Ser. No. 61/129,711 filed on Jul. 14, 2008, is hereby claimed.

### FIELD OF THE INVENTION

The present invention relates to the field of antennas, and more particularly to an orthomode junction assembly with associated filters for use in an antenna feed system based on reversed orthomode junction topology.

### BACKGROUND OF THE INVENTION

The current turnstile junction industry standard is a topology in which the four (4) branching waveguides are assigned to the lower frequency feed section (typically transmit (Tx) signal) and the high frequency feed section is aligned with the feed horn axis. Therefore, four (4) receive (Rx) band reject filters or other types of filters must be used to separate the Tx and Rx bands.

Such antenna feed systems tend to be large in volume and mass, especially at lower frequencies such as at C-band (between about 3.4 GHz and 6.8 GHz). The filters used in the Tx waveguides tend to have sections small in size thus limiting both peak and average power handling capabilities. A typical implementation of prior art antenna feed system is shown in FIG. 1

Accordingly, there is a need for an improved orthomode junction assembly with associated filters.

### SUMMARY OF THE INVENTION

It is therefore a general object of the present invention to provide an improved orthomode junction assembly with associated filters.

An advantage of the present invention is that in the orthomode junction assembly with associated filters, the Tx channel is using larger waveguide sections, therefore has lower insertion loss. This in turn results in higher average power handling. Larger waveguide cross-sections also improve peak power handling (multipactor threshold).

Another advantage of the present invention is that in the orthomode junction assembly, the Tx channel can be machined as a single piece including the Rx reject filter. Therefore, significant PIM (passive intermodulation) level reduction can be achieved.

A further advantage of the present invention is that in the orthomode junction assembly, the high frequency waveguides are used as branching network. High frequency waveguides are smaller in cross-section yielding a more compact and lower mass design.

Still another advantage of the present invention is that in the orthomode junction assembly, the high frequency waveguides can be recombined using either a magic tees (providing tracking capability by using the isolated magic tee port as the interface to the tracking receiver) or by simple reactive tees or by other types of combiners.

Yet another advantage of the present invention is that in the orthomode junction assembly, the Tx reject filters are much less complex (simple evanescent waveguides or the like) than the Rx reject filters used in the current design.

According to an aspect of the present invention there is provided an orthomode junction assembly with associated filters for use in an antenna feed system for transmitting and/or receiving a first electromagnetic signal at a first frequency range and receiving and/or transmitting a second electromagnetic signal at a second frequency range, the first frequency range being lower than the second frequency range, said junction assembly comprising:
an orthomode junction including an antenna port for connecting to an antenna and defining a main junction axis, an opposed first signal port generally coaxial with the junction axis to transmit and/or receive said first signal, and a second signal port generally perpendicular to the junction axis to transmit and/or receive said second signal, said second signal port being located between said antenna port and said first signal port;
a first signal channel having on-axis second signal reject filters connecting to the first signal port; and
a second signal channel having cross-axis first signal reject filters connecting to said second signal port.

Conveniently, the first and second signals are transmit and receive signals, respectively, such that said first and second signal ports are transmit and receive ports, respectively.

Preferably, the junction assembly further includes a signal combiner connecting to the second receive port of the second signal, said signal combiner providing tracking capability to the antenna feed system.

Typically, the signal combiner is a magic tee having an isolated port connecting to a tracking receiver so as to provide the tracking capability.

Conveniently, the on-axis second signal reject filters are radial stub filters or quad-cross iris/quad-ridge design filters.

Typically, the second port includes four outer ports orthogonal to each other.

Preferably, the second signal is a dual polarization signal, each said polarization being received via a respective pair of said outer ports, each said pair of outer ports including respective diametrically opposed ones of said outer ports.

Typically, each of said first and second signals is either a circularly polarized signal or a linearly polarized signal.

Other objects and advantages of the present invention will become apparent from a careful reading of the detailed description provided herein, with appropriate reference to the accompanying drawings.

### BRIEF DESCRIPTION OF THE DRAWINGS

Further aspects and advantages of the present invention will become better understood with reference to the description in association with the following Figures, in which similar references used in different Figures denote similar components, wherein:

FIG. 1 is a prior art schematic diagram of an orthomode junction assembly with associated filters for a circularly polarized antenna feed system, with the high frequency signal being propagated through an on-axis feed section and the low frequency signal being propagated through a branching feed section;

FIG. 2 is a schematic diagram of an orthomode junction assembly with associated filters for circularly polarized antenna feed system based on reversed orthomode junction topology in accordance with an embodiment of the present invention for dual mode (left hand (LH) and right hand (RH)) circular polarization Tx and Rx signals; and

FIG. 3 is a perspective view of the orthomode junction assembly of the embodiment of FIG. 2 with associated filters with circular polarization; and

FIGS. 4a to 4j are cross-sectional views of different axi-symmetric waveguide filters suitable for use in association with reversed orthomode junction assembly embodiments of the present invention.

### DETAILED DESCRIPTION OF THE PREFERRED EMBODIMENTS

With reference to the annexed drawings the preferred embodiment of the present invention will be herein described for indicative purpose and by no means as of limitation.

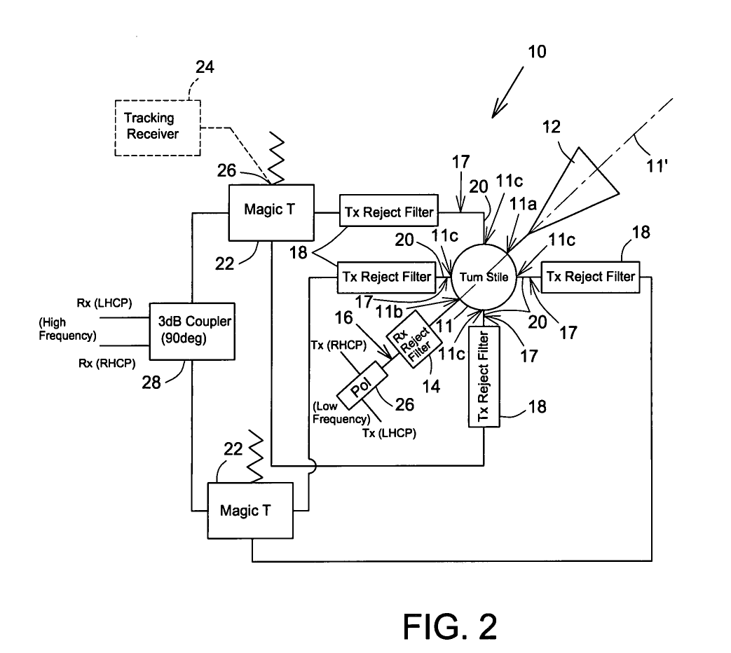

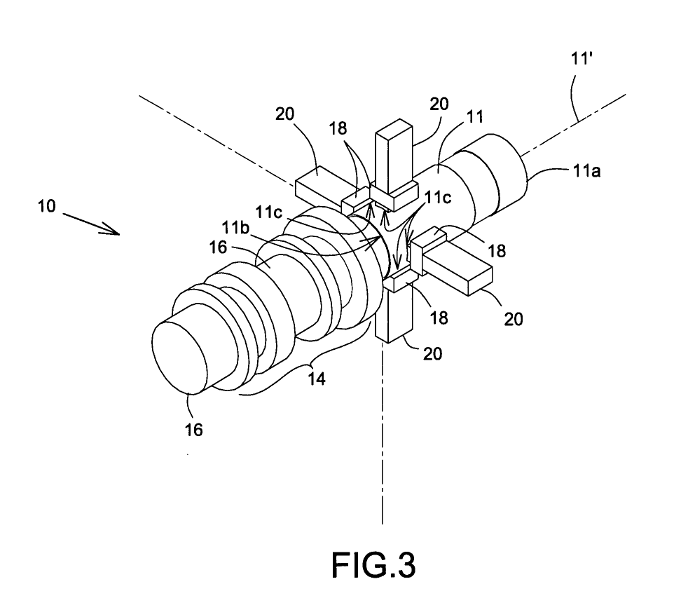

Referring to FIGS. 2 and 3, there is shown a schematic diagram of an antenna feed system based on reversed orthomode junction topology, with an embodiment 10 of a ‘reverse’ orthomode junction assembly with associated filters thereof, in accordance with the present invention, located in the feed chain of an antenna represented by a feed horn 12 or the like connected at an antenna output port 11a of an orthomode junction 11 (or also called turnstile junction) and defining a main junction axis 11′.

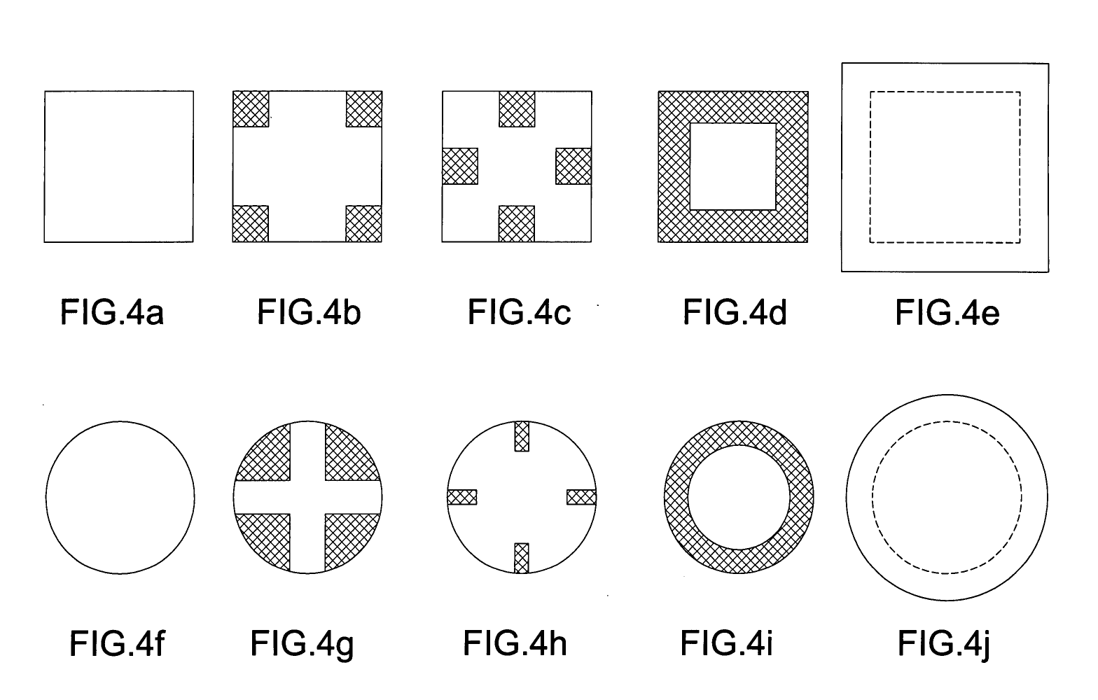

The key component of the design of the embodiment 10 of the present invention is an on-axis receive (Rx) reject filter 14 included in the low frequency, preferably transmit (Tx), channel 16 connected to a first signal port 11b of the junction 11, generally opposed and coaxial to the antenna port 11a, to transmit a first electromagnetic signal. This new filter 14 features such type of symmetry that allows propagating either circular (CP) or dual linear polarization signals. The only known type of such a filter 14 was until now an iris filter (as shown in FIGS. 4i and 4d) in circular (FIG. 4f) or square (FIG. 4a) waveguide. However this iris type of a filter has two significant disadvantages. Firstly it has reduced power handling capability since it is a bandpass network in its nature. Secondly, its rejection bandwidth is severely limited, typically to 1.3 of its center frequency.

In the present invention the filters 14 are preferably either stubs or radial stubs (as represented in FIG. 3 and shown in FIGS. 4e and 4j, respectively, and in which the dotted lines represent the respective cross-section of the waveguide) or quad-cross iris (as shown in FIGS. 4b and 4g)/quad-ridge designs (as shown in FIGS. 4c and 4h). The radial stubs filters 14 have superior power handling and extended band rejection characteristics allowing for practical designs in current Ka-band (between about 18 GHz and 30 GHz) and Ku-band (between about 10 GHz and 15 GHz) signal frequencies applications. The quad iris/ridge filter (FIGS. 4b, 4c, 4g and 4h) design is more complex, yields lower power handling but its rejection bandwidth is potentially larger (up to 2 times of its center passband frequency). Once such filter design is accomplished a reversed OMJ (orthomode junction) described previously becomes feasible.

Four (4) Tx band reject filters 18 of the high frequency, preferably receive (Rx), channel 17 are connected to the ports 20 of the junction 11 that are substantially orthogonal to each other. The four outer ports 20 form the cross-axis second signal port 11c of the orthomode junction 11 that is generally perpendicular to the junction axis 11′ receiving the second electromagnetic signal. The frequency range of the first Tx signal is lower than the frequency range of the second Rx signal. The first signal (Tx) reject filters 18 are typically stub filters, simple evanescent waveguides or the like.

Accordingly, in the preferred embodiment 10, the second signal is a dual polarization signal (left and right hand circular polarizations or vertical and horizontal linear polarizations), with each polarization being received via a respective pair of diametrically opposed outer ports 20.

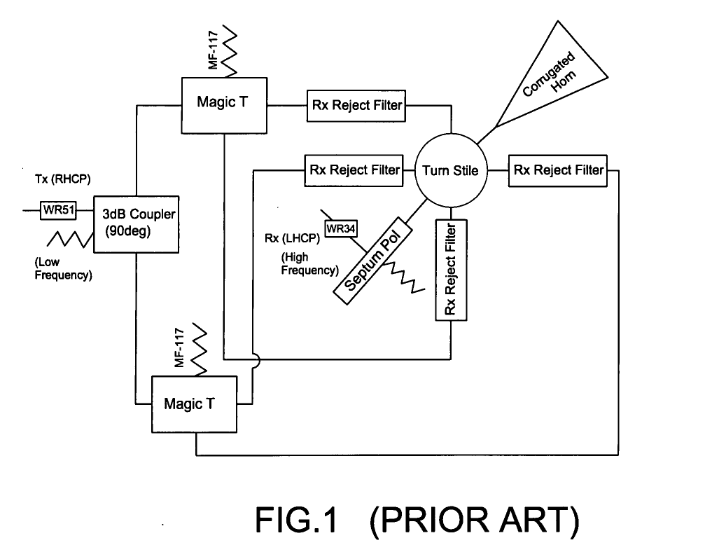

Preferably, the second signal outer ports (Rx) 20 of the second port 11c are connected to a combiner 22, such as a magic tees, simple reactive tees or the like. When magic tees 22 are used, the latter provide tracking capability to the antenna feed system. To this effect, a tracking receiver 24 (shown in dotted lines in FIG. 2) is generally connected to, or interfaces with the isolated port 26 of the magic tee 22, instead of using a load (as identified MF-117 in FIG. 1) thereat.

Although FIGS. 2 and 3 show circular polarization feed, as already mentioned, the present invention is obviously also applicable to linear polarization feed (not shown) in which the polarizer 26 (such as a septum polarizer or the like) is replaced by an orthomode transducer (OMT) (not shown), and for which, in the high frequency section (second signal four output ports), the 90 degree coupler 28 is simply removed.

Although the present invention has been described with a certain degree of particularity, it is to be understood that the disclosure has been made by way of example only and that the present invention is not limited to the features of the embodiments described and illustrated herein, but includes all variations and modifications within the scope and spirit of the invention as hereinafter claimed.

I claim:

1. An orthomode junction assembly with associated filters for use in an antenna feed system for transmitting and/or receiving a first electromagnetic signal at a first frequency range and receiving and/or transmitting a second electromagnetic signal at a second frequency range, the first frequency range being lower than the second frequency range, said junction assembly comprising:
an orthomode junction including an antenna port for connecting to an antenna and defining a main junction axis, an opposed first signal port generally coaxial with the junction axis to transmit and/or receive said first signal, and a second signal port generally perpendicular to the junction axis to transmit and/or receive said second signal, said second signal port being located between said antenna port and said first signal port;
a first signal channel having on-axis second signal reject filters connecting to the first signal port; and
a second signal channel having cross-axis first signal reject filters connecting to said second signal port.

2. The junction assembly of claim 1, wherein said first and second signals are transmit and receive signals, respectively, such that said first and second signal ports are transmit and receive ports, respectively.

3. The junction assembly of claim 2, further including a signal combiner connecting to the second receive port of the second signal, said signal combiner providing tracking capability to the antenna feed system.

4. The junction assembly of claim 3, wherein said signal combiner is a magic tee having an isolated port connecting to a tracking receiver so as to provide the tracking capability.

5. The junction assembly of claim 1, wherein the on-axis second signal reject filters are radial stub filters or quad-cross iris/quad-ridge design filters.

6. The junction assembly of claim 1, wherein said second port includes four outer ports orthogonal to each other.

7. The junction assembly of claim 6, wherein said second signal is a dual polarization signal, each said polarization being received via a respective pair of said outer ports, each said pair of outer ports including respective diametrically opposed ones of said outer ports.

8. The junction assembly of claim 7, wherein each of said first and second signals is either a circularly polarized signal or a linearly polarized signal.

9. The junction assembly of claim 1, wherein each of said first and second signals is either a circularly polarized signal or a linearly polarized signal.
